(19) United States
(12) Patent Application Publication
(10) Pub. No.: US 2026/0086118 A1
(43) Pub. Date: Mar. 26, 2026

(54) Direct Connectorization for High-Frequency Signals

(71) Applicant: FormFactor, Inc., Livermore, CA (US)

(72) Inventors: Pratik Bakul Ghate, Beaverton, OR (US); David Raschko, Sherwood, OR (US); Jerry Martyniuk, Portland, OR (US); John Ebner, Portland, OR (US); Timothy Lesher, Portland, OR (US); Edin Sijercic, Portland, OR (US); Shean McMahon, Seal Beach, CA (US); Ryan Garrison, Hood River, OR (US)

(21) Appl. No.: 19/338,686

(22) Filed: Sep. 24, 2025

Related U.S. Application Data
(60) Provisional application No. 63/698,976, filed on Sep. 25, 2024.

(51) Int. Cl. G01R 1/073; H05K 1/02

(52) U.S. Cl. CPC G01R 1/07307; H05K 1/0246

(57) ABSTRACT

Improved electrical connections to a probe head are provided by making electrical connections to a flexible circuit connected to the probes. Preferably these connections are solderless and made with a single ganged unit. Many advantages result compared to conventional approaches of making soldered connections to a flexible circuit, or coupling the flexible circuit to a printed circuit board (PCB) and making the connections from the PCB using semi-rigid coaxial cables.

### CROSS REFERENCE TO RELATED APPLICATIONS

This application claims priority from U.S. Provisional Patent Application 63/698976 filed Sep. 25, 2024, which is incorporated herein by reference.

### FIELD OF THE INVENTION

This invention relates to making electrical connections to a probe head, especially in connection with probing high frequency devices under test.

### BACKGROUND

Arrays of electrical probes are commonly used to make temporary electrical contact to a device or circuit under test. As technology evolves, it is necessary to probe at higher frequencies (e.g., mm-wave frequencies) for some applications (e.g., 5G applications). This technology evolution can cause various new problems to arise. Here we are concerned with connecting the probes to the rest of the test equipment (e.g., a vector network analyzer). Here the relevant probe connections are the permanent connections at bases of probes, instead of the temporary connections made by the probe tips.

The growing demand for 5G applications has driven need for mm Wave testing. Flexible circuits-based test has proven well suited to mm Wave test to date, but has many areas that can be improved. Specific among these are:
a) Improvements to signal integrity in the test signal path;
b) Reductions in PCB support component footprint (e.g. connectors, headers, etc.) to accommodate increasing extension circuitry requirements;
c) Increasing automation in assembly and manufacturing processes to improve product yield.

Complicating factors to realizing these improvements include:
a) A requirement for extension circuitry to be physically as close to the DUT as possible; and
b) PCBs serve as poor transmission media for mm Wave signals due to increasing signal losses as frequencies increase.

To mitigate these issues while simultaneously addressing the support needs for 5G/mm Wave test, a standardized, high-density interface is needed that can support but mm Wave requirements while simultaneously enabling connection between PCB-based extension circuitry.

Flexible circuit technology provides an excellent basis for this mitigation. However, current state-of-the-art (SOTA) in flexible circuit interconnects is either via low-parallelism connectors soldered directly to the flexible circuit or through complex physical launch structures coupled with semi-rigid coaxial cabling.

### On-Flexible Circuits Soldered Connectors

Soldered connectors minimize physical transitions and by extension signal interfaces which translates to good electrical performance and signal integrity. On the downside, these connectors tend to have low parallelism (typically 1 signal line per connector) and introduce a complex manufacturing process with potential for significant yield falloff. Flexible circuits are fabricated from low thermal mass dielectrics and can suffer from yield loss any time heat is applied. Generally, the larger the thermal mass of a component relative to that of the flexible circuits, the higher the probability of negative yield impact. Physical connectors have very large thermal mass relative to the flexible circuits and this mass increases with port count. One solution is to use numerous single port connectors which helps mitigate yield concerns, but instead consumes additional space on the flexible circuits which creates different challenges in space constrained applications like wafer probing.

### On-PCB Launches and Semi-Rigid Coaxial Cabling

A second SOTA technique is use of semi-rigid coax coupled with on-PCB launches. Here PCB is short for printed circuit board. In this approach, the flexible circuits makes contact with a series of physical interfaces on the PCB (a core-to-board interface or CBI). These CBI pads are connected to a physical launch structure via PCB traces. The launch structure serves to transition between the PCB traces and the semi-rigid coax. The semi-rigid coax then forms a signal path to a connector or elsewhere on the PCB.

Semi-rigid coax offers excellent signal integrity characteristics. The downside of this approach lies in the large number of physical transitions necessary to its implementation, making it an expensive solution. In a connectorized approach, there will be typically a single transition between the flexible circuits and the connector. In a semi-rigid coax approach, there are typically three the Core to Board Interface (CBI), probe tip, and the coax-to-connector. Each of these transitions introduces impedance discontinuities which have detrimental effects on high-frequency signals.

These existing methods and devices for flexible circuits interconnects have various disadvantages such as:
a) Extensive Hand Assembly Work
a1) Labor-Intensive Process: Relying on hand assembly for connecting individual coaxial launches is labor-intensive and time-consuming. Skilled technicians are required to ensure precision and accuracy, which significantly increases labor costs.
a2) Human Error: Manual assembly introduces a high risk of human error. Mistakes in soldering, connector placement, or alignment can lead to defects, affecting the overall quality and performance of the assembly.
a3) Inconsistency: Variations in the manual assembly process can result in inconsistency between units, leading to unpredictable performance and reliability issues. These inconsistencies are detrimental in high-frequency applications where precision is critical.
b) Assembly Yield Issues
b1) Low Yield Rates: Due to the complexity and precision required in hand assembly, yield rates can be low. A high rate of defective units necessitates rework or scrapping, which wastes materials and increases production costs.
b2) Quality Control Challenges: Ensuring consistent quality across all assembled units becomes a significant challenge. Each defect that passes through the assembly line can compromise the performance and reliability of the final product.
c) Expensive Extension Circuitry
c1) High Costs: The extension circuitry required in traditional methods is often costly. This circuitry is essential for maintaining signal integrity and performance, but its expense adds to the overall production cost.
c2) Amplified Yield Issues: The high cost of extension circuitry exacerbates the impact of assembly yield issues. Defective units that need rework or replacement mean more wasted expensive components, further driving up costs.
d) Impedance Mismatches
d1) Variability in Assembly: Hand assembly can result in slight differences in the semi-rigid coax length, connector placement and alignment and amount of solder used, all of which contributes to impedance mismatches. Impedance mismatches cause signal reflections, standing waves, and power losses, adversely affecting RF performance.
d2) Extension Circuitry Issues: The use of expensive extension circuitry, while necessary for signal integrity, can also introduces its own impedance challenges. Any inconsistencies or defects in this circuitry further exacerbate impedance mismatches.
d3) Hand Solder: Hand soldering introduces possible variations in solder quantity and end-joint quality. Excess solder increases capacitive parasitics leading to impedance mismatches. Solder joint quality variations can also impact signal integrity.
e) Increased Signal Loss
e1) Defective Components: Low yield rates mean that a higher number of components may be defective, leading to increased signal loss. This is especially critical in RF applications where even small losses can significantly impact performance.
e2) Testing and Rework: The need for extensive pre-assembly testing and potential rework can introduce additional handling and potential damage to components, further increasing signal loss.
f) Reduced Frequency Range and Bandwidth
f1) Assembly Precision: The high precision required for optimal RF performance is difficult to achieve consistently with hand assembly. This can limit the effective frequency range and bandwidth of the RF system, reducing its overall capability.
f2) Component Variability: Variability in component performance due to assembly inconsistencies can lead to a reduced effective operational bandwidth, impacting the flexibility and usefulness of the RF system.

### SUMMARY

The solution to the above-described challenges is to move to a connector mechanically attached directly to a flexible circuit.

The approach presented herein improves upon the state-of-the-art of existing high-frequency flexible circuit interconnect solutions. It is implemented as a direct transition from a flexible circuit to a high-frequency compression mount/pressure mount (solderless) connector typically ganged. This provides a more direct signal path providing immediate improvements in signal integrity, reduced manufacturing complexity, and lower fabrication costs.

Direct solderless connection of connectors to the flexible circuit overcomes heat-induced yield fallout. Further benefits of solderless connections include a simpler assembly process that has proven to offer superior connectivity to that observed with soldered connecters in our internal design experiments. Solderless connectors are available in a range of ports, thereby reducing assembly complexity for multiport designs.

Direct connectorization to the flexible circuit directly reduces the number of physical transitions necessary to move a signal between a source and a sink (e.g. on/off a flexible circuits contacting a DUT). This has direct positive consequences in terms of signal integrity for RF and other high frequency signals. A semi-rigid coax approach will typically see three times the number of interfaces, each introducing impedance discontinuities or other possibilities for signal degradation.

Use of on-flexible circuit connectors significantly simplifies manufacturing and assembly. Unlike semi-rigid coax, no PCB processes are involved, eliminating the complex physical launch structures necessary in semi-rigid coax. Connectors can be installed using fixturing which is more conducive to automated assembly techniques, and should a failure occur in the assembly process, rework is straightforward. Rework is not always possible with semi-rigid coax.

In comparison with the state of the art:
a) Soldered Semi-Rigid Coax vs Solderless Ganged Connectors: The conventional technique of using soldered semi-rigid coax connections imposes various challenges such as expensive assembly, possibility of human error (yield issues), and requires specialized assembly training to minimize the possibility of impedance mismatch. The new methodology of using solderless ganged connectors will mitigate the possibility of impedance mismatch.
b) Ganged connector vs individual connector solutions: In a non-ganged (individual connector) configuration, each connector operates independently. They are usually spaced apart and do not share any common mechanical or electrical features making them less cost and space efficient than ganged connectors. Compression mount ganged connectors are also known as multi-port connectors. Multiple ports are grouped together in a single housing or assembly providing advantages such as space efficiency, cost, flexibility to adjust the number of signals, field replacement, and ease of maintenance.

Significant advantages are provided relative to the state of the art. These include:
a) Improved Signal Integrity—This approach provides fewer signal transitions between the DUT and the test instrumentation. This reduced number of transitions directly translates to improved signal integrity over existing SOTA such as semi-rigid coax.
b) Flexible Implementation—This approach can be implemented directly on a flexible circuit strip combined with a CBI technique. Existing connector-on-flexible circuits techniques do not offer this degree of flexibility.
c) Simpler Manufacturing Process—This approach is implemented using mechanically attached connectors. The process is easily fixtured and offers numerous paths to full or partial automation.
d) Improved Manufacturing Yield—Through mechanical attachment of connectors, this technique eliminates the need for soldering of connectors. Soldering connectors directly applies large amounts of localized heat to heat-sensitive flexible circuits dielectrics which has directly traceable negative yield impacts.
e) Easy Repair—Soldered connectors cannot be replaced without high probability of irreparable heat damage to flexible circuits. This damage can manifest as delamination or physical melting of the flexible circuit materials. Semi-rigid coax offers slightly better opportunities for repair, but due to the extremely precise RF launch structures, success rates for these repairs have historically been left wanting.
f) More Automatable Solution—This approach offers assembly automation opportunities not possible with semi-rigid coax. Mechanically attached connectors can be fixtured. While soldered connectors can also be fixtured, the soldering process is complex and requires significant process development and optimization to mitigate potential heat damage to the flexible circuits. Further, this process carries some degree of product design variance relative to the amount of metal in the flexible circuits in proximity to the connector.
g) Improved RF performance—Using the connector directly with the flexible circuits offers better impedance control i.e. reduce impedance discontinuity resulting in improved the RF performance. Improved assembly techniques and better shielding reduce electromagnetic interference (EMI) and noise, enhancing the clarity and reliability of RF signals. The new technique reduces the reliance on hand assembly, ensuring more consistent and precise connections. This consistency minimizes impedance mismatches and signal losses, resulting in better overall signal integrity.
h) Improved density—The elimination of bulky individual connectors and the integration of ganged connector solutions allow for higher density of components on the PCB. This leads to more compact and space-efficient designs. Improved density enables more efficient use of PCB real estate, allowing for more complex and capable RF circuits in the same or smaller footprint.
i) Manufacturing quality improvements—Eliminating hand soldering and using compression mount ganged connectors reduces human error while increasing repeatability, making it easier to maintain high quality and consistency across all signal paths.
j) Improved field repairability—This approach favors modularity, making it easier to replace or repair specific components without needing to disassemble the entire system. Using standardized connectors and interfaces simplifies field repairs, allowing technicians to quickly diagnose and fix issues with minimal downtime.
k) Fewer signal transitions (Reduced impedance discontinuities)—Reducing the number of signal transitions by using more direct connections minimizes impedance discontinuities leading to smoother signal paths, reducing reflections and losses that degrade performance.
l) Enables inexpensive PCB materials for mm Wave frequencies—This technique allows the use of regular PCB materials such as FR-4 or Megtron 6 in place of expensive, exotic high-frequency materials like Tachyon and Megtron 7. This reduces costs and simplifies the manufacturing process.
m) Reduced Hand Assembly Work:
m1) Labor-Intensive: The process of manually assembling individual coaxial connectors is labor-intensive. It requires precision and skill, which leads to increased labor costs and time.
m2) Human Error: The reliance on hand assembly introduces the possibility of human error, which affects the overall quality and reliability of the connections. Mistakes in assembly lead to performance issues or failures in the system.
n) Elimination of CBI to PCB—Eliminating the use of the flexible circuits to PCB interface simplifies the entire design and assembly process. However, it requires alternative solutions to achieve the same level of performance and connectivity. Using connector systems designed for high-frequency applications can reduce the need for manual assembly and improve consistency and yield. These systems also provide better mechanical stability and ease of assembly.
o) Yield Issues—There are yield issues when using individual coax launches. These issues arise from inconsistencies in the assembly process, such as variations in connector placement or soldering quality. Low yield rates can result in a higher need for rework or scrapping of defective assemblies, leading to increased costs and waste.

### BRIEF DESCRIPTION OF THE DRAWINGS

FIGS. 1A-C show exemplary embodiments of the invention.

FIG. 2 shows exemplary waveguide features of an embodiment of the invention.

FIG. 3 shows exemplary termination features of an embodiment of the invention.

FIGS. 4A-B show alternative waveguide types suitable for use in embodiments of the invention.

### DETAILED DESCRIPTION

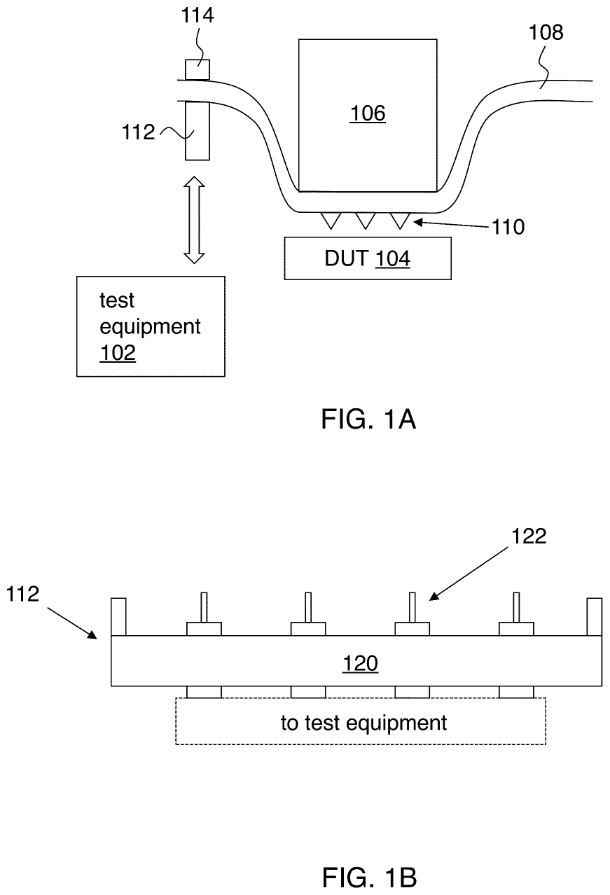

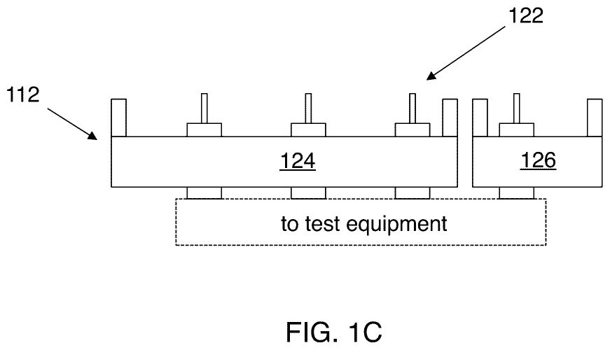

FIG. 1A shows an exemplary embodiment of the invention. This example is a probe head including an array of probes 110, a flexible circuit interconnect structure 108 electrically connected to the array of probes, and at least one connector 112 configured to make two or more electrical connections between a corresponding two or more individual cables and a corresponding two or more contacts of the flexible circuit interconnect structure. In operation, this probe head makes temporary electrical contact to device under test (DUT) 104, and the probe head typically includes a member 106 to provide mechanical support for flexible circuit 108. Connector 112 is in electrical communication with test equipment 102. In preferred embodiments, the electrical connections of connector 112 are solderless, which can be accomplished by clamping flexible circuit 108 between connector 112 and a support member 114 as shown.

FIG. 1B shows an example of a connector 112. Here connector 112 is a single ganged unit 120 configured to make all of the electrical connections, e.g., with a “bed of nails” formed by coaxial cable ends 122. Although it is often preferred to have a single connector as in this example, any number of connectors can also be employed. FIG. 1C shows an example where connector 112 includes two units, 124 and 126.

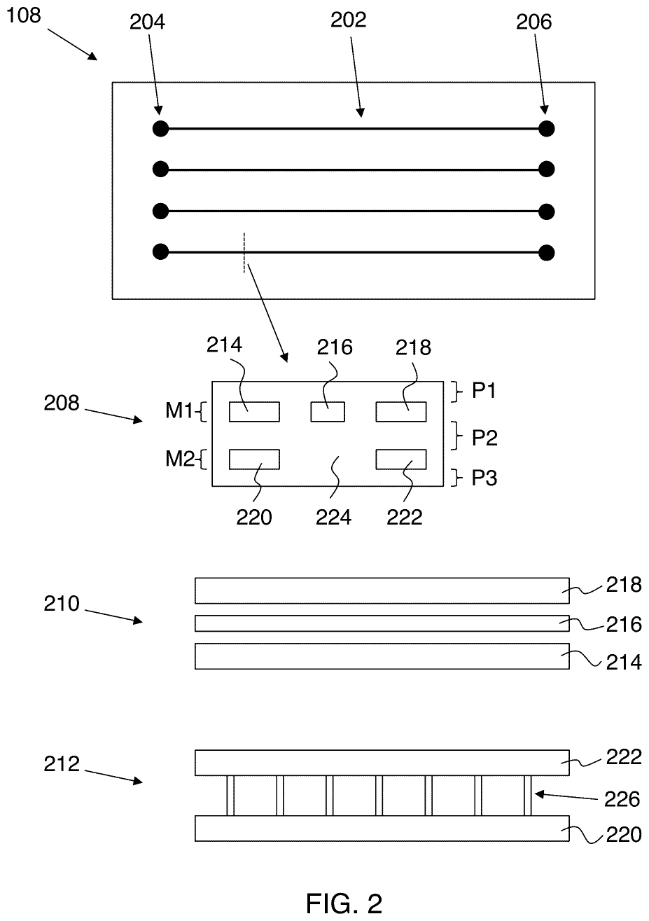

FIG. 2 shows exemplary waveguide geometry for the flexible circuit 108. Here waveguides 202 connect terminations 204 to terminations 206. The view of 208 is a cross section of one of these waveguides. Here M1 and M2 are the metal pattern layers, and are vertically sandwiched between polymer layers P1, P2, P3. The view of 210 is a top view of the M1 pattern, showing a coplanar waveguide with center conductor 216 and side conductors 214 and 218 (214 and 218 are also referred to as ground strips). The view of 212 is a top view of the M2 pattern showing auxiliary strips 220 and 222 connected to each other via ground straps 226. The purpose of the M2 pattern layer is to provide extra ground return and more signal shielding than one would have in a pure coplanar waveguide structure (i.e., if only the M1 pattern layer were present), without altering the impedance of the coplanar waveguide of the M1 pattern. The purpose of ground straps 226 is to prevent this structure from supporting undesirable higher-order modes. These RF (radio frequency) design considerations are known in the art, and so are not further described here. It is also well known in the art how to make structures as shown in the example of FIG. 2 in flexible circuit technology (e.g., in metal-polyimide multi-layer composite structures), so that is also not further described here.

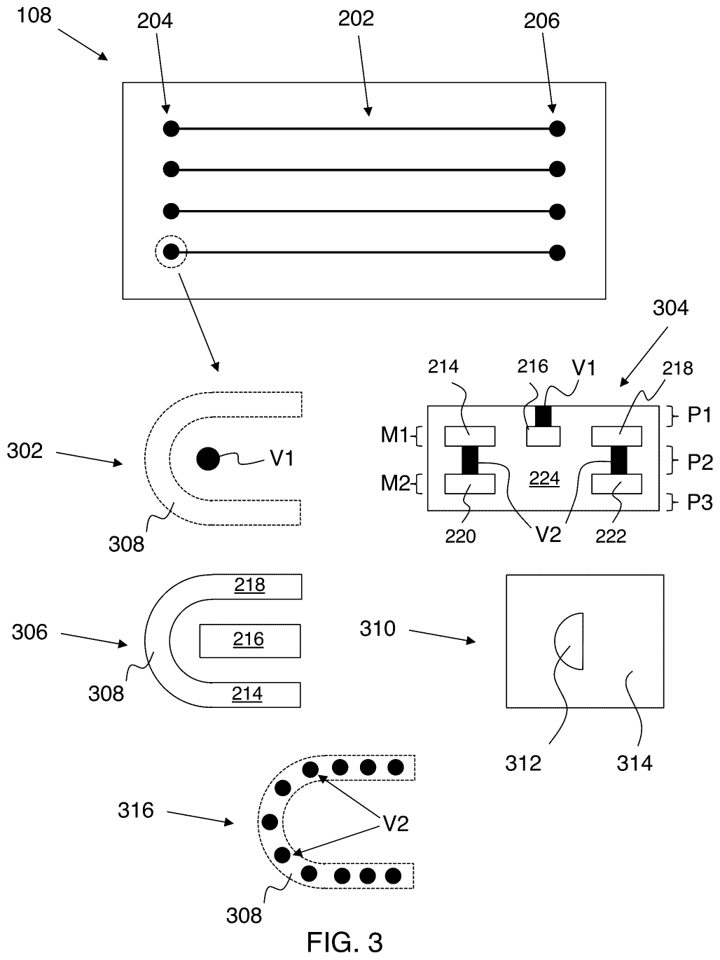

FIG. 3 shows exemplary terminations for flexible circuit 108. Here view 302 is a top view of the circled termination of flexible circuit 108, and 304 is a schematic cross section view of the termination. V1 is a via that makes contact to center conductor 216 of the waveguide and extends to the surface of flexible circuit 108, as shown in the view of 304. The view of 306 is the M1 pattern at the termination, which includes a semicircular segment 308 joining side conductors 214 and 218. The view of 310 shows the M2 pattern at the termination, which is a metal ground plane 314 with a cutout 312 disposed below via V1. The view of 316 shows the pattern of vias V2 disposed to connect the grounded parts of the M1 pattern of this termination to ground plane 314. These vias are preferably present to improve shielding of the termination, suppress higher order modes and/or to avoid unnecessary resonance.

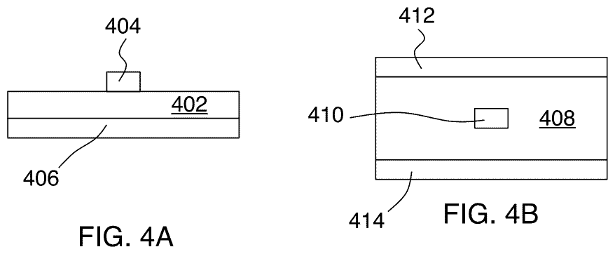

The preceding examples are implemented using coplanar waveguides but this approach can be extended to other transmission line types including microstrips and striplines. FIG. 4A shows a microstrip cross section and FIG. 4B shows a stripline cross section. Here 402 is the dielectric and 404, 406 are the conductors for the microstrip. Similarly, 408 is the dielectric for the stripline and 410, 412, 414 are the conductors for the stripline. In particular, 406, 412 and 414 are ground conductors, while 404 and 410 are signal conductors.

1. A probe head for electrical testing, the probe head comprising:
an array of probes;
a flexible circuit interconnect structure electrically connected to the array of probes; and
at least one connector configured to make two or more electrical connections between a corresponding two or more individual cables and a corresponding two or more contacts of the flexible circuit interconnect structure.

2. The probe head of claim 1, wherein the at least one connector is configured as a single ganged unit to make all of the two or more electrical connections.

3. The probe head of claim 1, wherein the at least one connector is configured as two or more discrete connectors to make all of the two or more electrical connections.

4. The probe head of claim 1, wherein an operation frequency of the probe head is 40 GHz or more.

5. The probe head of claim 1, wherein the flexible circuit interconnect structure includes two or more conductive transmission lines connecting the array of probes to the two or more individual cables.

6. The probe head of claim 5, wherein the two or more conductive transmission lines are selected from the group consisting of: coplanar waveguides, striplines and microstrips.

7. The probe head of claim 5, wherein at least one of the two or more conductive transmission lines is a coplanar waveguide.

8. The probe head of claim 7, wherein the coplanar waveguide includes a vertically separated ground structure.

9. The probe head of claim 8, wherein the vertically separated ground structure is configured as two auxiliary strips disposed beneath ground strips of the coplanar waveguide.

10. The probe head of claim 9, wherein the two auxiliary strips are connected to each other by periodically spaced ground straps.

11. The probe head of claim 8, wherein a termination structure of the coplanar waveguide includes two or more vias disposed to vertically connect a ground strip of the coplanar waveguide to the vertically separated ground structure.

12. The probe head of claim 1, wherein the two or more electrical connections are solderless.
